(19) United States
(12) Patent Application Publication
(10) Pub. No.: US 2025/0320232 A1
(43) Pub. Date: Oct. 16, 2025

(54) METAL-CONTAINING PRECURSORS

(71) Applicant: ENTEGRIS, INC., Billerica, MA (US)

(72) Inventor: Drew Michael Hood, Newtown, CT (US)

(21) Appl. No.: 19/173,783

(22) Filed: Apr. 8, 2025

Related U.S. Application Data
(60) Provisional application No. 63/632,892, filed on Apr. 11, 2024.

(51) Int. Cl. C07F 5/00; C23C 16/30; C23C 16/40

(52) U.S. Cl. CPC C07F 5/00; C23C 16/303; C23C 16/407

(57) ABSTRACT

Methods for forming a vapor deposition precursor are provided. The method comprises contacting a metal halide compound, a Grignard reagent, and a carbodiimide compound to form the vapor deposition precursor. The vapor deposition precursor comprises at least one of an indium amidinate, a gallium amidinate, or any combination thereof. The vapor deposition precursor is formed without use of a pyrophoric compound. Various compositions comprising a vapor deposition precursor and related systems and devices are also provided.

### CROSS-REFERENCE TO RELATED APPLICATIONS

This application claims the benefit under 35 USC 119 of U.S. Provisional Patent Application No. 63/632,892, filed Apr. 11, 2025, the disclosure of which is hereby incorporated herein by reference in its entirety.

### FIELD

The present disclosure relates to metal-containing precursors and related compositions, methods, devices, and systems.

### BACKGROUND

Conventional methods for synthesizing metal-containing precursors can present risks because of the reagents being used and the reaction conditions being employed.

### SUMMARY

Some embodiments relate to a method for forming a vapor deposition precursor. In some embodiments, the method comprises contacting a metal halide compound, a Grignard reagent, and a carbodiimide compound to form the vapor deposition precursor. In some embodiments, the metal halide comprises at least one of a gallium halide, an indium halide, or any combination thereof. In some embodiments, the vapor deposition precursor comprises at least one of a gallium amidinate, an indium amidinate, or any combination thereof.

Some embodiments relate to a composition. In some embodiments, the composition comprises a vapor deposition precursor comprising a metal amidinate. In some embodiments, the metal amidinate comprises at least one of a gallium amidinate, an indium amidinate, or any combination thereof. In some embodiments, the metal amidinate has the characteristics defined by the following process step(s): contacting a metal halide compound, a Grignard reagent, and a carbodiimide compound to form the vapor deposition precursor. In some embodiments, the metal halide compound comprises at least one of a gallium halide, an indium halide, or any combination thereof.

Some embodiments relate to a method for forming a film. In some embodiments, the method comprises one or more of the following steps: obtaining at least a vapor deposition precursor comprising at least one of a gallium amidinate, an indium amidinate, or any combination thereof; and exposing a substrate to at least the vapor deposition precursor, under vapor deposition conditions, to form a film on the substrate.

### DRAWINGS

FIG. 1 is a flowchart of a method for synthesizing a precursor, according to some embodiments.

FIG. 2 is a flowchart of a method for making a metal-containing film, according to some embodiments.

### DETAILED DESCRIPTION

As used herein, the term “alkyl” refers to a hydrocarbyl having from 1 to 30 carbon atoms. The alkyl may be attached via a single bond. An alkyl having n carbon atoms may be designated as a “Ca alkyl.” For example, a “C₃ alkyl” may include n-propyl and isopropyl. An alkyl having a range of carbon atoms, such as 1 to 30 carbon atoms, may be designated as a C₁-C₃₀ alkyl. In some embodiments, the alkyl is linear. In some embodiments, the alkyl is branched. In some embodiments, the alkyl is substituted. In some embodiments, the alkyl is unsubstituted. In some embodiments, the alkyl comprises or is selected from the group consisting of at least one of a C₁-C₃₀ alkyl, C₁-C₂₉ alkyl, C₁-C₂₈ alkyl, C₁-C₂₇ alkyl, C₁-C₂₇ alkyl, C₁-C₂₆ alkyl, C₁-C₂₅ alkyl, C₁-C₂₄ alkyl, C₁-C₂₃ alkyl, C₁-C₂₂ alkyl, C₁-C₂₁ alkyl, C₁-C₂₀ alkyl, C₁-C₁₉ alkyl, C₁-C₁₈ alkyl, C₁-C₁₇ alkyl, C₁-C₁₆ alkyl, C₁-C₁₅ alkyl, C₁-C₁₄ alkyl, C₁-C₁₃ alkyl, C₁-C₁₂ alkyl, C₁-C₁₁ alkyl, C₁-C₁₀ alkyl, a C₁-C₉ alkyl, a C₁-C₈ alkyl, a C₁-C₇ alkyl, a C₁-C₆ alkyl, a C₁-C₅ alkyl, a C₁-C₄ alkyl, a C₁-C₃ alkyl, a C₁-C₂ alkyl, a C₂-C₃₀ alkyl, a C₃-C₃₀ alkyl, a C₄-C₃₀ alkyl, a C₅-C₃₀ alkyl, a C₆-C₃₀ alkyl, a C₇-C₃₀ alkyl, a C₈-C₃₀ alkyl, a C₉-C₃₀ alkyl, a C₁₀-C₃₀ alkyl, a C₁₁-C₃₀ alkyl, a C₁₂-C₃₀ alkyl, a C₁₃-C₃₀ alkyl, a C₁₄-C₃₀ alkyl, a C₁₅-C₃₀ alkyl, a C₁₆-C₃₀ alkyl, a C₁₇-C₃₀ alkyl, a C₁₈-C₃₀ alkyl, a C₁₉-C₃₀ alkyl, a C₂₀-C₃₀ alkyl, a C₂₁-C₃₀ alkyl, a C₂₂-C₃₀ alkyl, a C₂₃-C₃₀ alkyl, a C₂₄-C₃₀ alkyl, a C₂₅-C₃₀ alkyl, a C₂₆-C₃₀ alkyl, a C₂₇-C₃₀ alkyl, a C₂₈-C₃₀ alkyl, a C₂₉-C₃₀ alkyl, a C₂-C₁₀ alkyl, a C₃-C₁₀ alkyl, a C₄-C₁₀ alkyl, a C₅-C₁₀ alkyl, a C₆-C₁₀ alkyl, a C₇-C₁₀ alkyl, a C₈-C₁₀ alkyl, a C₂-C₉ alkyl, a C₂-C₈ alkyl, a C₂-C₇ alkyl, a C₂-C₆ alkyl, a C₂-C₅ alkyl, a C₃-C₅ alkyl, or any combination thereof. In some embodiments, the alkyl comprises or is selected from the group consisting of at least one of methyl, ethyl, n-propyl, 1-methylethyl (iso-propyl), n-butyl, iso-butyl, sec-butyl, n-pentyl, 1,1-dimethylethyl (t-butyl), n-pentyl, iso-pentyl, n-hexyl, isohexyl, 3-methylhexyl, 2-methylhexyl, heptyl, octyl, nonyl, decyl, dodecyl, octadecyl, or any combination thereof. In some embodiments, the term “alkyl” refers generally to alkyls, alkenyls, alkynyls, and/or cycloalkyls.

As used herein, the term “alkenyl” refers to a hydrocarbyl having from 1 to 30 carbon atoms and at least one carbon-carbon double bond. In some embodiments, the alkenyl comprises or is selected from the group consisting of at least one of a C₁-C₃₀ alkenyl, C₁-C₂₉ alkenyl, C₁-C₂₈ alkenyl, C₁-C₂₇ alkenyl, C₁-C₂₇ alkenyl, C₁-C₂₆ alkenyl, C₁-C₂₅ alkenyl, C₁-C₂₄ alkenyl, C₁-C₂₃ alkenyl, C₁-C₂₂ alkenyl, C₁-C₂₁ alkenyl, C₁-C₂₀ alkenyl, C₁-C₁₉ alkenyl, C₁-C₁₈ alkenyl, C₁-C₁₇ alkenyl, C₁-C₁₆ alkenyl, C₁-C₁ alkenyl, C₁-C₁₄ alkenyl, C₁-C₁₃ alkenyl, C₁-C₁₂ alkenyl, C₁-C₁₁ alkenyl, C₁-C₁₀ alkenyl, a C₁-C₉ alkenyl, a C₁-C₈ alkenyl, a C₁-C₇ alkenyl, a C₁-C₆ alkenyl, a C₁-C₅ alkenyl, a C₁-C₄ alkenyl, a C₁-C₃ alkenyl, a C₁-C₂ alkenyl, a C₂-C₃₀ alkenyl, a C₃-C₃₀ alkenyl, a C₄-C₃₀ alkenyl, a C₅-C₃₀ alkenyl, a C₆-C₃₀ alkenyl, a C₇-C₃₀ alkenyl, a C₈-C₃₀ alkenyl, a C₉-C₃₀ alkenyl, a C₁₀-C₃₀ alkenyl, a C₁₁-C₃₀ alkenyl, a C₁₂-C₃₀ alkenyl, a C₁₃-C₃₀ alkenyl, a C₁₄-C₃₀ alkenyl, a C₁₅-C₃₀ alkenyl, a C₁₆-C₃₀ alkenyl, a C₁₇-C₃₀ alkenyl, a C₁₈-C₃₀ alkenyl, a C₁₉-C₃₀ alkenyl, a C₂₀-C₃₀ alkenyl, a C₂₁-C₃₀ alkenyl, a C₂₂-C₃₀ alkenyl, a C₂₃-C₃₀ alkenyl, a C₂₄-C₃₀ alkenyl, a C₂₅-C₃₀ alkenyl, a C₂₆-C₃₀ alkenyl, a C₂₇-C₃₀ alkenyl, a C₂₈-C₃₀ alkenyl, a C₂₉-C₃₀ alkenyl, a C₂-C₁₀ alkenyl, a C₃-C₁₀ alkenyl, a C₄-C₁₀ alkenyl, a C₅-C₁₀ alkenyl, a C₆-C₁₀ alkenyl, a C₇-C₁₀ alkenyl, a C₈-C₁₀ alkenyl, a C₂-C₉ alkenyl, a C₂-C₈ alkenyl, a C₂-C₇ alkenyl, a C₂-C₆ alkenyl, a C₂-C₅ alkenyl, a C₃-C₅ alkenyl, or any combination thereof. Examples of alkenyl groups include, without limitation, at least one of vinyl, allyl, 1-methylvinyl, 1-propenyl, 1-butenyl, 2-butenyl, 3-butenyl, 1,3-butadienyl, 2-methyl-1-propenyl, 2-methyl-2-propenyl, 1-pentenyl, 2-pentenyl, 3-pentenyl, 4-pentenyl, 1,3-pentadienyl, 2,4-pentadienyl, 1,4-pentadienyl, 3-methyl-2-butenyl, 1-hexenyl, 2-hexenyl, 3-hexenyl, 1,3-hexadienyl, 1,4-hexadienyl, 2-methylpentenyl, 1-heptenyl, 3-heptenyl, 1-octenyl, 1,3-octadienyl, 1-nonenyl, 2-nonenyl, 3-nonenyl, 1-decenyl, 3-decenyl, 1-undecenyl, oleyl, linoleyl, linolenyl, or any combination thereof.

As used herein, the term “alkynyl” refers to a hydrocarbyl having from 1 to 30 carbon atoms and at least one carbon-carbon triple bond. In some embodiments, the alkynyl comprises or is selected from the group consisting of at least one of a C₁-C₃₀ alkynyl, C₁-C₂₉ alkynyl, C₁-C₂₈ alkynyl, C₁-C₂₇ alkynyl, C₁-C₂₇ alkynyl, C₁-C₂₆ alkynyl, C₁-C₂₅ alkynyl, C₁-C₂₄ alkynyl, C₁-C₂₃ alkynyl, C₁-C₂₂ alkynyl, C₁-C₂₁ alkynyl, C₁-C₂₀ alkynyl, C₁-C₁₉ alkynyl, C₁-C₁₈ alkynyl, C₁-C₁₇ alkynyl, C₁-C₁₆ alkynyl, C₁-C₁₅ alkynyl, C₁-C₁₄ alkynyl, C₁-C₁₃ alkynyl, C₁-C₁₂ alkynyl, C₁-C₁₁ alkynyl, C₁-C₁₀ alkynyl, a C₁-C₉ alkynyl, a C₁-C₈ alkynyl, a C₁-C₇ alkynyl, a C₁-C₆ alkynyl, a C₁-C₅ alkynyl, a C₁-C₄ alkynyl, a C₁-C₃ alkynyl, a C₁-C₂ alkynyl, a C₂-C₃₀ alkynyl, a C₃-C₃₀ alkynyl, a C₄-C₃₀ alkynyl, a C₅-C₃₀ alkynyl, a C₆-C₃₀ alkynyl, a C₇-C₃₀ alkynyl, a C₈-C₃₀ alkynyl, a C₉-C₃₀ alkynyl, a C₁₀-C₃₀ alkynyl, a C₁₁-C₃₀ alkynyl, a C₁₂-C₃₀ alkynyl, a C₁₃-C₃₀ alkynyl, a C₁₄-C₃₀ alkynyl, a C₁₅-C₃₀ alkynyl, a C₁₆-C₃₀ alkynyl, a C₁₇-C₃₀ alkynyl, a C₁₈-C₃₀ alkynyl, a C₁₉-C₃₀ alkynyl, a C₂₀-C₃₀ alkynyl, a C₂₁-C₃₀ alkynyl, a C₂₂-C₃₀ alkynyl, a C₂₃-C₃₀ alkynyl, a C₂₄-C₃₀ alkynyl, a C₂₅-C₃₀ alkynyl, a C₂₆-C₃₀ alkynyl, a C₂₇-C₃₀ alkynyl, a C₂₈-C₃₀ alkynyl, a C₂₉-C₃₀ alkynyl, a C₂-C₁₀ alkynyl, a C₃-C₁₀ alkynyl, a C₄-C₁₀ alkynyl, a C₅-C₁ alkynyl, a C₆-C₁₀ alkynyl, a C₇-C₁₀ alkynyl, a C₈-C₁₀ alkynyl, a C₂-C₉ alkynyl, a C₂-C₈ alkynyl, a C₂-C₇ alkynyl, a C₂-C₆ alkynyl, a C₂-C₅ alkynyl, a C₃-C₅ alkynyl, or any combination thereof. Examples of alkynyl groups include, without limitation, at least one of ethynyl, propynyl, n-butynyl, n-pentynyl, 3-methyl-1-butynyl, n-hexynyl, methyl-pentynyl, or any combination thereof.

As used herein, the term “cycloalkyl” refers to a non-aromatic carbocyclic ring having from 3 to 8 carbon atoms in the ring. The term includes a monocyclic non-aromatic carbocyclic ring and a polycyclic non-aromatic carbocyclic ring. The term “monocyclic,” when used as a modifier, refers to a cycloalkyl having a single cyclic ring structure. The term “polycyclic,” when used as a modifier, refers to a cycloalkyl having more than one cyclic ring structure, which may be fused, bridged, spiro, or otherwise bonded ring structures. For example, two or more cycloalkyls may be fused, bridged, or fused and bridged to obtain the polycyclic non-aromatic carbocyclic ring. In some embodiments, the cycloalkyl may comprise, consist of, or consist essentially of, or may be selected from the group consisting of, at least one of cyclopropyl, cyclobutyl, cyclopentyl, cyclohexyl, cycloheptyl, cyclooctyl, or any combination thereof.

As used herein, the term “aryl” refers to a monocyclic or polycyclic aromatic hydrocarbon. The number of carbon atoms of the aryl may be in a range of 5 carbon atoms to 100 carbon atoms. In some embodiments, the aryl has 5 to 20 carbon atoms. For example, in some embodiments, the aryl has 6 to 8 carbon atoms, 6 to 10 carbon atoms, 6 to 12 carbon atoms, 6 to 15 carbon atoms, or 6 to 20 carbon atoms. The term “monocyclic,” when used as a modifier, refers to an aryl having a single aromatic ring structure. The term “polycyclic,” when used as a modifier, refers to an aryl having more than one aromatic ring structure, which may be fused, bridged, spiro, or otherwise bonded ring structures. In some embodiments, the aryl is —C₆H₅.

Non-limiting examples of aryls include, without limitation, at least one of benzene, toluene, xylene (e.g., o-xylene, m-xylene, p-xylene), t-butyltoluene (e.g., o-t-butyltoluene, m-t-butyltoluene, p-t-butyltoluene), ethylmethylbenzene (e.g., 1-ethyl-4-methylbenzene, 1-ethyl-3-methylbenzene), 1-isopropyl-4-methylbenzene, 1-t-butyl-4-methylbenzene, mesitylene, pseudocumene, durene, methylbenzene, dimethylbenzene, trimethylbenzene, ethylbenzene, diethylbenzene (e.g., 1,4-diethylbenzene), triethylbenzene, propylbenzene, butylbenzene, iso-butylbenzene, sec-butylbenzene, t-butylbenzene, hexylbenzene, styrene, naphthalene, anthracene, phenanthrene, biphenyl, terphenyl, methylnaphthalene, biphenylene, dimethylnaphthalene, methylanthracene, 4,4′-dimethylbiphenyl, bibenzyl, diphenylmethane, any isomer thereof, or any combination thereof, and the like.

As used herein, the term “halide” refers to a —Cl, —Br, —I, or —F.

As used herein, the term “contacting” refers to bringing two or more components into immediate or close proximity, or into direct contact.

Some embodiments relate to precursors and related methods. At least some of these embodiments relate to precursors useful in the fabrication of microelectronic devices, including semiconductor devices, and the like. For example, the precursors can be used to form metal-containing films by one or more deposition processes. Examples of metal-containing films include, for example and without limitation, at least one of indium oxides, indium nitrides, gallium oxides, gallium nitrides, others disclosed herein, or any combination thereof, among others. Examples of deposition processes include, without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof. In some embodiments, the precursors disclosed herein are useful for area selective deposition.

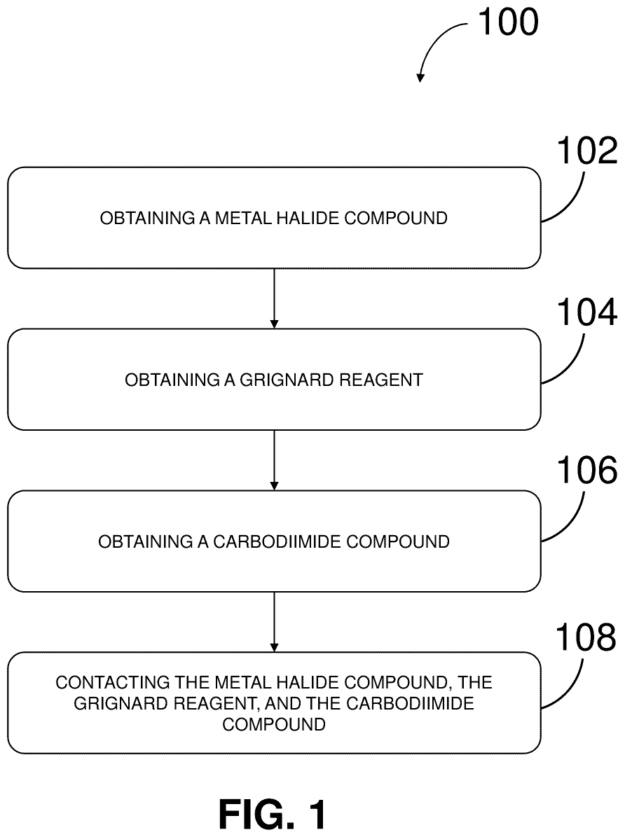

FIG. 1 is a flowchart of a method for synthesizing a precursor, according to some embodiments. As shown in FIG. 1, the method comprises one or more of the following steps: obtaining 102 a metal halide compound; obtaining 104 a Grignard reagent; obtaining 106 a carbodiimide compound; and contacting 108 the metal halide compound, the Grignard reagent, and the carbodiimide compound to form a vapor deposition precursor. In some embodiments, the vapor deposition precursor comprises a metal amidinate. In some embodiments, the method is performed without use of a pyrophoric compound.

At step 102, the method for synthesizing a precursor comprises obtaining a metal halide compound. In some embodiments, the metal halide compound comprises at least one of a metal bromide, a metal chloride, a metal fluoride, a metal iodide, or any combination thereof. In some embodiments, the metal halide compound comprises a metal trihalide. In some embodiments, the metal halide compound comprises a compound of the formula: MX₃, where M is a metal and X is independently a halide. In some embodiments, the M comprises at least one of In, Ga, or any combination thereof. In some embodiments, the metal halide compound comprises a metal tribromide (MBr₃). In some embodiments, the metal halide compound comprises a metal trichloride (MCl₃). In some embodiments, the metal halide compound comprises a metal trifluoride (MF₃). In some embodiments, the metal halide compound comprises a metal triiodide (MI₃). In some embodiments, at least two of the halides of the metal halide compound are different.

In some embodiments, the metal halide compound comprises at least one of an indium bromide, an indium chloride, an indium fluoride, an indium iodide, or any combination thereof. In some embodiments, the metal halide compound comprises an indium trihalide. In some embodiments, the metal halide compound comprises a compound of the formula: MX₃, where M is an indium and X is independently a halide. In some embodiments, the metal halide compound comprises an indium tribromide (InBr₃). In some embodiments, the metal halide compound comprises an indium trichloride (InCl₃). In some embodiments, the metal halide compound comprises an indium trifluoride (InF₃). In some embodiments, the metal halide compound comprises an indium triiodide (InI₃). In some embodiments, at least two of the halides of the indium halide compound are different.

In some embodiments, the metal halide compound comprises at least one of a gallium bromide, a gallium chloride, a gallium fluoride, a gallium iodide, or any combination thereof. In some embodiments, the metal halide compound comprises a gallium trihalide. In some embodiments, the metal halide compound comprises a compound of the formula: MX₃, where M is a gallium and X is independently a halide. In some embodiments, the metal halide compound comprises a gallium tribromide (GaBr₃). In some embodiments, the metal halide compound comprises a gallium trichloride (GaCl₃). In some embodiments, the metal halide compound comprises a gallium trifluoride (GaF₃). In some embodiments, the metal halide compound comprises a gallium triiodide (GaI₃). In some embodiments, at least two of the halides of the gallium halide compound are different.

At step 104, the method for synthesizing a precursor comprises obtaining a Grignard reagent. In some embodiments, the Grignard reagent comprises a compound of the formula:

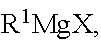

where:
R¹ is at least one of an alkyl, an alkenyl, an alkyne, an aryl, a cycloalkyl, or any combination thereof;
X is a halide.

In some embodiments, R¹ comprises an alkyl and X is Cl, Br, or I.

In some embodiments, R¹ comprises an alkenyl and X is Cl, Br, or I.

In some embodiments, R¹ comprises an alkyne and X is Cl, Br, or I.

In some embodiments, R¹ comprises an aryl and X is Cl, Br, or I.

In some embodiments, R¹ comprises a cycloalkyl and X is Cl, Br, or I.

At step 106, the method for synthesizing a precursor comprises obtaining a carbodiimide compound. In some embodiments, the carbodiimide compound comprises a compound of the formula:

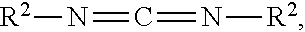

where:
R² is independently at least one of an alkyl, a cycloalkyl, or any combination thereof.

In some embodiments, R² comprises an alkyl. In some embodiments, R² comprises a cycloalkyl. In some embodiments, R² is different.

At step 108, the method for synthesizing a precursor comprises contacting the metal halide compound, the Grignard reagent, and the carbodiimide compound to form a vapor deposition precursor. In some embodiments, the contacting comprises bringing the metal halide compound, the Grignard reagent, and the carbodiimide compound into close or immediate proximity. In some embodiments, the contacting comprises bringing the metal halide compound, the Grignard reagent, and the carbodiimide compound into direct physical contact. In some embodiments, the contacting comprises stirring the metal halide compound, the Grignard reagent, and the carbodiimide compound. In some embodiments, the contacting comprises mixing the metal halide compound, the Grignard reagent, and the carbodiimide compound. In some embodiments, the contacting comprises agitating the metal halide compound, the Grignard reagent, and the carbodiimide compound. In some embodiments, the contacting comprises adding the metal halide compound, the Grignard reagent, and the carbodiimide compound to a reaction vessel (e.g., a flask, a vial, etc.). In some embodiments, the contacting comprises combining the metal halide compound, the Grignard reagent, and the carbodiimide compound in a reaction vessel. In some embodiments, the metal halide compound, the Grignard reagent, and the carbodiimide are contacted sequentially, in any order. In some embodiments, the metal halide compound, the Grignard reagent, and the carbodiimide compound are contacted substantially simultaneously or simultaneously.

In some embodiments, the Grignard reagent comprises a compound of the formula:

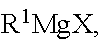

where:
R¹ is an alkyl; and
X is Cl, Br, or I; and
the carbodiimide compound comprises a compound of the formula:

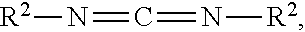

where:
R² is independently an alkyl.

In some embodiments, the Grignard reagent comprises a compound of the formula:

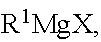

where:
R¹ is a C₁-C₂ alkyl; and
X is Cl, Br, or I; and
the carbodiimide compound comprises a compound of the formula:

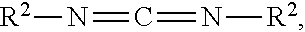

where:
R² is 1-methylethyl (iso-propyl).

In some embodiments, the Grignard reagent comprises a compound of the formula:

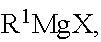

where:
R¹ is an alkenyl; and
X is Cl, Br, or I; and
the carbodiimide compound comprises a compound of the formula:

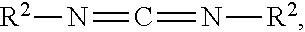

where:
R² is independently an alkyl.

In some embodiments, the Grignard reagent comprises a compound of the formula:

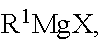

where:
R¹ is an alkenyl; and
X is Cl, Br, or I; and
the carbodiimide compound comprises a compound of the formula:

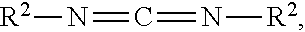

where:
R² is independently a cycloalkyl.

In some embodiments, the Grignard reagent comprises a compound of the formula:

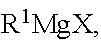

where:
R¹ is an alkyne; and
X is Cl, Br, or I; and
the carbodiimide compound comprises a compound of the formula:

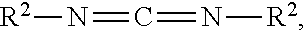

where:
R² is independently an alkyl.

In some embodiments, the Grignard reagent comprises a compound of the formula:

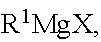

where:
R¹ is an alkyne; and
X is Cl, Br, or I; and
the carbodiimide compound comprises a compound of the formula:

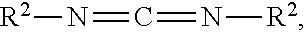

where:
R² is independently a cycloalkyl.

In some embodiments, the Grignard reagent comprises a compound of the formula:

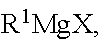

where:
R¹ is an aryl; and
X is Cl, Br, or I; and
the carbodiimide compound comprises a compound of the formula:

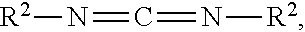

where:
R² is independently an alkyl.

In some embodiments, the Grignard reagent comprises a compound of the formula:

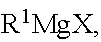

where:
R¹ is an aryl; and
X is Cl, Br, or I; and
the carbodiimide compound comprises a compound of the formula:

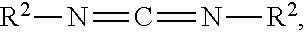

where:
R² is independently a cycloalkyl.

In some embodiments, the Grignard reagent comprises a compound of the formula:

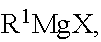

where:
R¹ is a cycloalkyl; and
X is Cl, Br, or I; and
the carbodiimide compound comprises a compound of the formula:

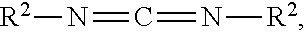

where:
R² is independently an alkyl.

In some embodiments, the Grignard reagent comprises a compound of the formula:

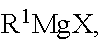

where:
R¹ is a cycloalkyl; and
X is Cl, Br, or I; and
the carbodiimide compound comprises a compound of the formula:

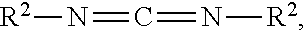

where:
R² is independently a cycloalkyl.

In some embodiments, the vapor deposition precursor comprises at least one of an indium amidinate compound, a gallium amidinate compound, or any combination thereof. In some embodiments, the vapor deposition precursor comprises at least one of an indium amidinate, a gallium amidinate, or any combination thereof. In some embodiments, the vapor deposition precursor comprises a compound of the formula:

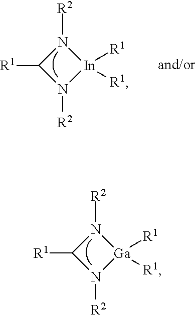

where:
R¹ is independently at least one of an alkyl, an alkenyl, an alkyne, an aryl, a cycloalkyl, or any combination thereof; and
R² is independently an alkyl.

In some embodiments, R¹ is the same. In some embodiments, at least one R¹ is different.

In some embodiments, the vapor deposition precursor comprises a compound of the formula:

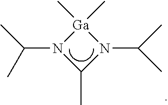

In some embodiments, the vapor deposition precursor comprises a compound of the formula:

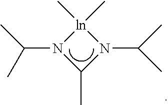

In some embodiments, the vapor deposition precursor is formed without use of a pyrophoric compound. In some embodiments, the vapor deposition precursor is formed without use of at least one of trimethyl gallium (Ga(CH₃)₃), dimethyl gallium chloride ((CH₃)₂GaCl), trimethyl indium (In(CH₃)₃), dimethyl indium chloride ((CH₃)₂InCl), methyl lithium, or any combination thereof. In some embodiments, the method does not comprise a step comprising a pyrophoric compound. For example, in some embodiments, the method does not comprise a step of contacting at least one of the metal halide compound, the Grignard reagent, the carbodiimide compound, or any combination thereof, with a pyrophoric compound.

### Example: Synthesis of [MeC(NⁱPr)₂]GaMe₂

In a nitrogen filled glovebox, 44.02 g of GaCl₃ (250 mmol) was added to a 1 L 3-neck round bottom flask equipped with a stir bar, an air-cooled condenser, a thermocouple, and an addition funnel. 50 mL of pentane was added to the flask forming a suspension to which 50 mL of tetrahydrofuran (THF) was added to the addition funnel and slowly added resulting in an exotherm that refluxed the solvent, note that the addition rate and pentane reflux were used to control the exotherm. Once the THF addition was complete, the resulting clear colorless solution was allowed to cool to room temperature. Then, 31.55 g of N,N′-diisopropylcarbodiimide (DIC) (250 mmol, 1 eq) was added to a 100 mL round bottom before being diluted with 50 mL of THF. Then 250 mL of MeMgBr (3.0 M in THF, 750 mmol, 3 eq) was added to a 500 mL round bottom flask along with a stir bar. The DIC solution was slowly added to the stirring MeMgBr solution which resulted in an exotherm. Once the addition was complete the resulting solution was allowed to stir for 30 mins before being transferred to the addition funnel and slowly added to the stirring GaCl₃ solution. Addition of the MeMgBr and DIC solution resulted in another exotherm that was controlled by the addition rate along with solvent refluxing facilitated by the air-cooled condenser. Once the addition was complete, the resulting reaction mixture was allowed to stir overnight. Then, 50 mL of pentane was added to precipitate magnesium salts before filtering through a disposable polypropylene filter into a 1 L Schlenk flask. The filter was washed with an additional 50 mL of pentane resulting in a pale-yellow filtrate. The solvent was then removed under reduced pressure resulting in a suspended white solid mixture. The product was then extracted with 100 mL of pentane and filtered again before the solvent was removed under reduced pressure to yield the crude product as a pale-yellow liquid. The crude material was then purified by vacuum distillation using a short path apparatus with a condenser cooled to −5° C., a pot temperature of 45° C., a head temperature of 34° C., and a baseline pressure of 300 mTorr. The pure [MeC(NⁱPr)₂]GaMe₂ product was isolated as a clear colorless liquid, yield 39.76 g (66%).

¹H NMR (400 MHz, C₆D₆): δ 3.27 (sept, 2H, CHCMe₂), 1.33 (s, 3H, MeC), 0.95 (d, 12H, CHCMe₂), 0.11 (s, 6H, AlMe)

### Example: Synthesis of [MeC(NⁱPr)₂]InMe₂

In a nitrogen filled glovebox, 55.29 g of InCl₃ (250 mmol) was added to a 1 L 3-neck round bottom flask equipped with a stir bar, an air-cooled condenser, a thermocouple, and an addition funnel. Next, 100 mL of THF was added to the flask which, with stirring, slowly dissolved the InCl₃ over the course of 2 hrs. 31.55 g of N,N′-Diisopropylcarbodiimide (DIC) (250 mmol, 1 eq) was added to a 100 mL round bottom before being diluted with 50 mL of THF. Then 250 mL of MeMgBr (3.0 M in THF, 750 mmol, 3 eq) was added to a 500 mL round bottom flask along with a stir bar. The DIC solution was slowly added to the stirring MeMgBr solution which resulted in an exotherm. Once the addition was complete the resulting solution was allowed to stir for 30 mins before being transferred to the addition funnel and slowly added to the stirring InCl3 solution. Addition of the MeMgBr and DIC solution resulted in another exotherm that was controlled by the addition rate along with solvent refluxing facilitated by the air-cooled condenser. The resulting reaction mixture was allowed to stir overnight. Then 50 mL of pentane was added to precipitate magnesium salts before filtering through a disposable polypropylene filter into a 1 L Schlenk flask. The filter was washed with an additional 50 mL of pentane resulting in a pale-yellow filtrate. The solvent was then removed under reduced pressure resulting in a suspended white solid mixture. The product was then extracted with 100 mL of pentane and filtered again before the solvent was removed under reduced pressure to yield the crude product as a pale-yellow liquid. The crude material was then purified by vacuum distillation using a short path apparatus with a condenser cooled to −5° C., a pot temperature of 55° C., a head temperature of 28° C., and a pressure of 250 mTorr. The pure [MeC(NⁱPr)₂]InMe₂ product was isolated as a clear colorless liquid, yield 51.48 g (72%).

¹H NMR (400 MHz, C₆D₆): δ 3.36 (sept, 2H, CHCMe₂), 1.42 (s, 3H, MeC), 0.91 (d, 12H, CHCMe₂), 0.15 (s, 6H, AlMe)

Some embodiments relate to a composition. In some embodiments, the composition comprises a precursor. In some embodiments, the composition comprises a vapor deposition precursor. In some embodiments, the composition comprises a vapor deposition precursor formed according to the methods disclosed herein. In some embodiments, the vapor deposition precursor comprises an indium amidinate. In some embodiments, the indium amidinate is a reaction product of an indium halide compound, a Grignard reagent, and a carbodiimide compound. In some embodiments, the indium amidinate has the characteristics defined by the following process step(s): contacting an indium halide compound, a Grignard reagent, and a carbodiimide compound to form the vapor deposition precursor. In some embodiments, the vapor deposition precursor comprises a gallium amidinate. In some embodiments, gallium amidinate is a reaction product of a gallium halide compound, a Grignard reagent, and a carbodiimide compound. In some embodiments, the gallium amidinate has the characteristics defined by the following process step(s): contacting a gallium halide compound, a Grignard reagent, and a carbodiimide compound to form the vapor deposition precursor. It will be appreciated that the indium amidinate and/or gallium amidinate can have characteristics defined by any one or more of the methods disclosed herein; however, for simplicity, the methods disclosed herein are not repeated here.

In some embodiments, the vapor deposition precursor comprises a compound of the formula:

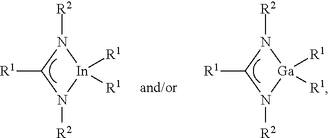

where:
R¹ is independently at least one of an alkyl, an alkenyl, an alkyne, an aryl, a cycloalkyl, or any combination thereof; and
R² is independently at least one of an alkyl, a cycloalkyl, or any combination thereof.

In some embodiments, R¹ is the same. In some embodiments, at least one R¹ is different.

In some embodiments, R¹ is an alkyl and R² is an alkyl.

In some embodiments, R¹ is an alkyl and R² is a cycloalkyl.

In some embodiments, R¹ is an alkenyl and R² is an alkyl.

In some embodiments, R¹ is an alkenyl and R² is a cycloalkyl.

In some embodiments, R¹ is an alkyne and R² is an alkyl.

In some embodiments, R¹ is an alkyne and R² is a cycloalkyl.

In some embodiments, R¹ is an aryl and R² is an alkyl.

In some embodiments, R¹ is an aryl and R² is a cycloalkyl.

In some embodiments, R¹ is a cycloalkyl and R² is an alkyl.

In some embodiments, R¹ is a cycloalkyl and R² is a cycloalkyl.

In some embodiments, the vapor deposition precursor comprises a compound of the formula:

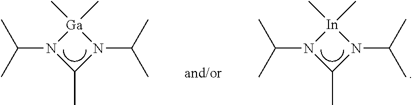

In some embodiments, the composition comprises less than 5% by weight of a pyrophoric compound based on a total weight of the composition. In some embodiments, the composition comprises less than 4% by weight of a pyrophoric compound based on a total weight of the composition. In some embodiments, the composition comprises less than 3% by weight of a pyrophoric compound based on a total weight of the composition. In some embodiments, the composition comprises less than 2% by weight of a pyrophoric compound based on a total weight of the composition. In some embodiments, the composition comprises less than 1% by weight of a pyrophoric compound based on a total weight of the composition. In some embodiments, the composition comprises less than 0.1% by weight of a pyrophoric compound based on a total weight of the composition. In some embodiments, the composition comprises less than 0.5% by weight of a pyrophoric compound based on a total weight of the composition. In some embodiments, the composition comprises less than 0.1% by weight of a pyrophoric compound based on a total weight of the composition. In some embodiments, the composition comprises less than 0.01% by weight of a pyrophoric compound based on a total weight of the composition. In some embodiments, the composition comprises less than 0.001% by weight of a pyrophoric compound based on a total weight of the composition. In some embodiments, the composition does not comprise a pyrophoric compound. In some embodiments, the weight percentage of pyrophoric compounds is assessed by Nuclear Magnetic Resonance (NMR).

In some embodiments, the composition comprises 0.001% to 5% by weight of a pyrophoric compound based on a total weight of the composition, or any range or subrange between 0.001% and 5%. For example, in some embodiments, the composition comprises 0.001% to 4%, 0.001% to 3%, 0.001% to 2%, 0.001% to 1%, 0.001% to 0.1%, 0.001% to 0.01%, 0.01% to 5%, 0.1% to 5%, 1% to 5%, 2% to 5%, 3% to 5%, or 4% to 5% by weight of a pyrophoric compound based on a total weight of the composition. The pyrophoric compound may comprise any one or more of the pyrophoric compounds disclosed herein. Non-limiting examples of pyrophoric compounds include, for example and without limitation, at least one of trimethyl gallium (Ga(CH₃)₃), dimethyl gallium chloride ((CH₃)₂GaCl), trimethyl indium (In(CH₃)₃), dimethyl indium chloride ((CH₃)₂InCl), methyl lithium, or any combination thereof. It will be appreciated that the pyrophoric compound may include other types of pyrophoric compounds, without departing from the scope of this disclosure.

In some embodiments, the vapor deposition precursor has a purity of 95% to 99.9999%, or any range or subrange between 95% and 99.9999%. For example, in some embodiments, the vapor deposition precursor has a purity of 96% to 99.9999%, 97% to 99.9999%, 98% to 99.9999%, 99% to 99.9999%, 99.9% to 99.9999%, 99.99% to 99.9999%, 99.999% to 99.9999%, 95% to 99.999%, 95% to 99.99%, 95% to 99.9%, 95% to 99% 95% to 98%, 95% to 97%, or 95% to 96%.

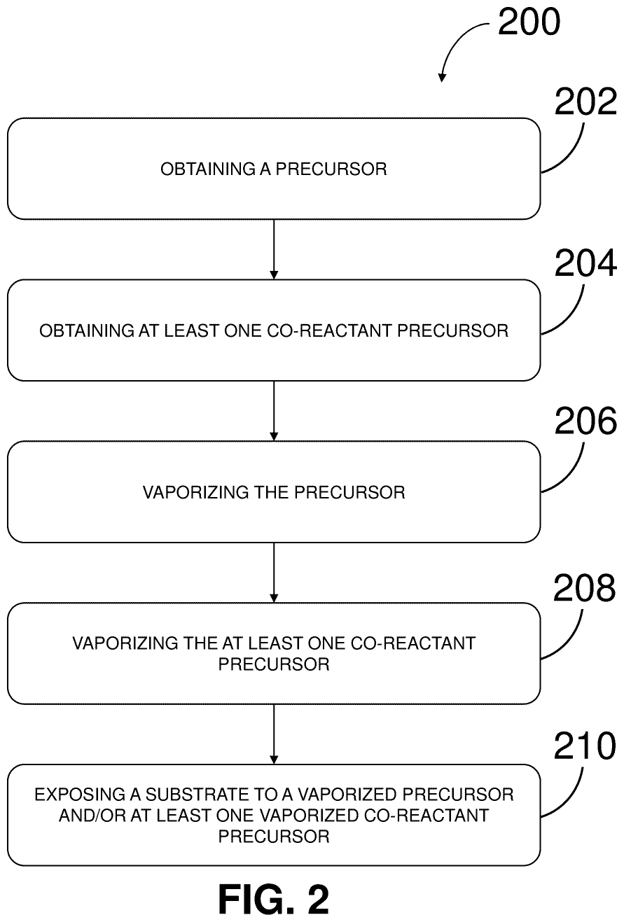

FIG. 2 is a flowchart of a method for making a film 200, according to some embodiments. As shown in FIG. 2, the method for making a film 200 may comprise one or more of the following steps: obtaining 202 a precursor, obtaining 204 at least one co-reactant precursor, vaporizing 206 the precursor to obtain a vaporized precursor, vaporizing 208 the at least one co-reactant precursor to obtain at least one vaporized co-reactant precursor, exposing 210, under vapor deposition conditions, a substrate to at least one of the vaporized precursor, the at least one vaporized co-reactant precursor, or any combination thereof, to form a film on the substrate.

At step 202, in some embodiments, the method comprises obtaining a precursor. The precursor may comprise any one or more of the vapor deposition precursors disclosed herein. For example, in some embodiments, the precursor comprises at least one of an indium amidinate, a gallium amidinate, or any combination thereof. In some embodiments, the obtaining comprises obtaining a vessel comprising the precursor. In some embodiments, the obtaining comprises obtaining a container comprising the precursor. In some embodiments, the precursor may be obtained in a container or other vessel in which the precursor is to be vaporized.

At step 204, in some embodiments, the method comprises obtaining at least one co-reactant precursor. In some embodiments, the at least one co-reactant precursor comprises at least one of an oxidizing gas, a reducing gas, a hydrocarbon, or any combination thereof. The at least one co-reactant precursor may be selected to obtain a desired film. In some embodiments, the at least one co-reactant precursor comprises at least one of N₂, H₂, NH₃, N₂H₄, CH₃HNNH₂, CH₃HNNHCH₃, NCH₃H₂, NCH₃CH₂H₂, N(CH₃)₂H, N(CH₃CH₂)₂H, N(CH₃)₃, N(CH₃CH₂)₃, Si(CH₃)₂NH, pyrazoline, pyridine, ethylene diamine, a radical thereof, or any combination thereof. In some embodiments, the at least one co-reactant precursor comprises at least one of H₂, O₂, O₃, H₂O, H₂O₂, NO, N₂O, NO₂, CO, CO₂, a carboxylic acid, an alcohol, a diol, a radical thereof, or any combination thereof. In some embodiments, the at least one co-reactant precursor comprises at least one of methane, ethane, ethylene, acetylene, or any combination thereof. The obtaining may comprise obtaining a container or other vessel comprising the at least one co-reactant precursor. In some embodiments, the at least one co-reactant precursor may be obtained in a container or other vessel in which the at least one co-reactant precursor is to be vaporized. In some embodiments, the method further comprises an inert gas, such as, for example, at least one of argon, helium, nitrogen, or any combination thereof.

At step 206, in some embodiments, the method comprises vaporizing the precursor to obtain a vaporized precursor. The vaporizing may comprise heating the precursor sufficient to obtain the vaporized precursor. In some embodiments, the vaporizing comprises heating a container comprising the precursor. In some embodiments, the vaporizing comprises heating the precursor in a deposition chamber in which the vapor deposition process is performed. In some embodiments, the vaporizing comprises heating a conduit for delivering the precursor, the vaporized precursor, or any combination thereof to, for example, a deposition chamber. In some embodiments, the vaporizing comprises operating a vapor delivery system comprising the precursor. In some embodiments, the vaporizing comprises heating to a temperature sufficient to vaporize the precursor to obtain the vaporized precursor. In some embodiments, the vaporizing comprises heating to a temperature below a decomposition temperature of at least one of the precursor, the vaporized precursor, or any combination thereof. In some embodiments, the precursor may be present in a gas phase or other vaporizable phase, in which case the step 206 is optional and not required. For example, in some embodiments, the precursor comprises the vaporized precursor.

At step 208, in some embodiments, the method comprises vaporizing the at least one co-reactant precursor to obtain the at least one vaporized co-reactant precursor. In some embodiments, the vaporizing comprises heating the at least one co-reactant precursor sufficient to obtain the at least one vaporized co-reactant precursor. In some embodiments, the vaporizing comprises heating a container comprising the at least one co-reactant precursor. In some embodiments, the vaporizing comprises heating the at least one co-reactant precursor in a deposition chamber in which the vapor deposition process is performed. In some embodiments, the vaporizing comprises heating a conduit for delivering the at least one co-reactant precursor, the at least one vaporized co-reactant precursor, or any combination thereof to, for example, a deposition chamber. In some embodiments, the vaporizing comprises operating a vapor delivery system comprising the at least one co-reactant precursor. In some embodiments, the vaporizing comprises heating to a temperature sufficient to vaporize the at least one co-reactant precursor to obtain the at least one vaporized co-reactant precursor. In some embodiments, the vaporizing comprises heating to a temperature below a decomposition temperature of at least one of the at least one co-reactant precursor, the at least one vaporized co-reactant precursor, or any combination thereof. In some embodiments, the at least one co-reactant precursor may be present in a gas phase or other vaporizable phase, in which case the step 208 is optional and not required. For example, in some embodiments, the at least one co-reactant precursor comprises the at least one vaporized co-reactant precursor.

At step 210, in some embodiments, the method comprises exposing, under vapor deposition conditions, a substrate to at least one of the vaporized precursor, the at least one vaporized co-reactant precursor, or any combination thereof, to form a film on the substrate. The exposing may be performed in any system, apparatus, device, assembly, chamber thereof, or component thereof suitable for vapor deposition processes, including, for example and without limitation, a deposition chamber, among others. In some embodiments, the exposing comprises contacting the substrate with at least one of the vaporized precursor, the at least one vaporized co-reactant precursor, or any combination thereof. The vaporized precursor and the at least one co-reactant precursor may be contacted with the substrate at the same time or at different times. For example, each of the vaporized precursor, the at least one vaporized co-reactant precursor, and the substrate may be present in the deposition chamber at the same time. That is, in some embodiments, the contacting may comprise contemporaneous contacting or simultaneous contacting of the vaporized precursor and the at least one vaporized co-reactant precursor with the substrate. Alternatively, each of the vaporized precursor and the at least one vaporized co-reactant precursor may be present in the deposition chamber at different times. That is, in some embodiments, the contacting may comprise alternate and/or sequential contacting, in one or more cycles, of the vaporized precursor with the substrate and subsequently contacting the at least one vaporized co-reactant precursor with the substrate.

The vapor deposition conditions may comprise conditions for vapor deposition processes. Examples of vapor deposition conditions include, without limitation, vapor deposition conditions for vapor deposition processes including at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

The vapor deposition conditions may comprise a deposition temperature. The deposition temperature may be a temperature less than the thermal decomposition temperature of at least one of the vaporized precursor, the at least one vaporized co-reactant precursor, or any combination thereof. The deposition temperature may be sufficiently high to reduce or avoid condensation of at least one of the vaporized precursor, the at least one vaporized co-reactant precursor, or any combination thereof. In some embodiments, the substrate may be heated to the deposition temperature. In some embodiments, the chamber or other vessel in which the substrate is contacted with the vaporized precursor and the at least one vaporized co-reactant precursor is heated to the deposition temperature. In some embodiments, at least one of the vaporized precursor, the at least one vaporized co-reactant precursor, or any combination thereof may be heated to the deposition temperature.

The deposition temperature may be a temperature of 200° C. to 2500° C., or any range or subrange between 200° C. and 2500° C. In some embodiments, the deposition temperature may be a temperature of 500° C. to 700° C. For example, in some embodiments, the deposition temperature may be a temperature of 500° C. to 680° C., 500° C. to 660° C., 500° C. to 640° C., 500° C. to 620° C., 500° C. to 600° C., 500° C. to 580° C., 500° C. to 560° C., 500° C. to 540° C., 500° C. to 520° C., 520° C. to 700° C., 540° C. to 700° C., 560° C. to 700° C., 580° C. to 700° C., 600° C. to 700° C., 620° C. to 700° C., 640° C. to 700° C., 660° C. to 700° C., or 680° C. to 700° C. In other embodiments, the deposition temperature may be a temperature of greater than 200° C. to 2500° C., such as, for example and without limitation, a temperature of 400° C. to 2000, 500° C. to 2000° C., 550° C. to 2400° C., 600° C. to 2400° C., 625° C. to 2400° C., 650° C. to 2400° C., 675° C. to 2400° C., 700° C. to 2400° C., 725° C. to 2400° C., 750° C. to 2400° C., 775° C. to 2400° C., 800° C. to 2400° C., 825° C. to 2400° C., 850° C. to 2400° C., 875° C. to 2400° C., 900° C. to 2400° C., 925° C. to 2400° C., 950° C. to 2400° C., 975° C. to 2400° C., 1000° C. to 2400° C., 1025° C. to 2400° C., 1050° C. to 2400° C., 1075° C. to 2400° C., 1100° C. to 2400° C., 1200° C. to 2400° C., 1300° C. to 2400° C., 1400° C. to 2400° C., 1500° C. to 2400° C., 1600° C. to 2400° C., 1700° C. to 2400° C., 1800° C. to 2400° C., 1900° C. to 2400° C., 2000° C. to 2400° C., 2100° C. to 2400° C., 2200° C. to 2400° C., 2300° C. to 2400° C., 500° C. to 2000° C., 500° C. to 1900° C., 500° C. to 1800° C., 500° C. to 1700° C., 500° C. to 1600° C., 500° C. to 1500° C., 500° C. to 1400° C., 500° C. to 1300° C., 500° C. to 1200° C., 500° C. to 1100° C., 500° C. to 1000° C., 500° C. to 1000° C., 500° C. to 900° C., or 500° C. to 800° C.

The vapor deposition conditions may comprise a deposition pressure. In some embodiments, the deposition pressure may comprise a vapor pressure of at least one of the vaporized precursor, the at least one vaporized co-reactant precursor, or any combination thereof. In some embodiments, the deposition pressure may comprise a chamber pressure.

The deposition pressure may be a pressure of 0.001 Torr to 100 Torr, or any range or subrange between 0.001 Torr and 100 Torr. For example, in some embodiments, the deposition pressure may be a pressure of 1 Torr to 30 Torr, 1 Torr to 25 Torr, 1 Torr to 20 Torr, 1 Torr to 15 Torr, 1 Torr to 10 Torr, 5 Torr to 50 Torr, 5 Torr to 40 Torr, 5 Torr to 30 Torr, 5 Torr to 20 Torr, or 5 Torr to 15 Torr. In other embodiments, the deposition pressure may be a pressure of 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, 95 Torr to 100 Torr, 1 Torr to 95 Torr, 1 Torr to 90 Torr, 1 Torr to 85 Torr, 1 Torr to 80 Torr, 1 Torr to 75 Torr, or 1 Torr to 70 Torr. In other further embodiments, the deposition pressure may be a pressure of 1 mTorr to 100 mTorr, 1 mTorr to 90 mTorr, 1 mTorr to 80 mTorr, 1 mTorr to 70 mTorr, 1 mTorr to 60 mTorr, 1 mTorr to 50 mTorr, 1 mTorr to 40 mTorr, 1 mTorr to 30 mTorr, 1 mTorr to 20 mTorr, 1 mTorr to 10 mTorr, 100 mTorr to 300 mTorr, 150 mTorr to 300 mTorr, 200 mTorr to 300 mTorr, or 150 mTorr to 250 mTorr, or 150 mTorr to 225 mTorr.

The substrate may comprise at least one of Si, Co, Cu, Al, W, WN, WC, TiN, Mo, MoC, SiO₂, W, SiN, WCN, Al₂O₃, AlN, ZrO₂, La₂O₃, TaN, RuO₂, IrO₂, Nb₂O₃, Y₂O₃, hafnium oxide, or any combination thereof.

In some embodiments, the film comprises at least one of an indium compound, a gallium compound, or any combination thereof. For example, in some embodiments, the film comprises at least one of a gallium, an indium, an indium oxide compound, an indium nitride compound, an indium oxynitride compound, an indium carbide compound, an indium carbonitride compound, a gallium oxide compound, a gallium nitride compound, a gallium oxynitride compound, a gallium carbide compound, a gallium carbonitride compound, or any combination thereof.

Some embodiments relate to a film on a substrate. In some embodiments, the film comprises any film formed according to the methods disclosed herein. In some embodiments, the film comprises any film prepared from any one or more of the precursors disclosed herein.

Any one or more of the embodiments disclosed herein shall be understood to be combinable without departing from the scope or spirit of the disclosure.

### ASPECTS

Various Aspects are described below. It is to be understood that any one or more of the features recited in the following Aspect(s) can be combined with any one or more other Aspect(s).
Aspect 1. A method for forming a vapor deposition precursor, the method comprising:
   contacting a metal trihalide, a Grignard reagent, and a carbodiimide compound to form the vapor deposition precursor,
      wherein the metal trihalide comprises at least one of a gallium trihalide, an indium trihalide, or any combination thereof;
      wherein the vapor deposition precursor comprises at least one of a gallium amidinate, an indium amidinate, or any combination thereof.
Aspect 2. The method according to Aspect 1, wherein the vapor deposition precursor is formed without use of a pyrophoric compound.
Aspect 3. The method according to any one of Aspects 1-2, wherein the vapor deposition precursor is formed without use of at least one of trimethyl gallium (Ga(CH₃)₃), dimethyl gallium chloride ((CH₃)₂GaCl), trimethyl indium (In(CH₃)₃), dimethyl indium chloride ((CH₃)₂InCl), methyl lithium, or any combination thereof.
Aspect 4. The method according to any one of Aspects 1-3, wherein the Grignard reagent comprises a compound of the formula:

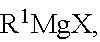

where:
   R¹ is at least one of an alkyl, an alkenyl, an alkyne, an aryl, a cycloalkyl, or any combination thereof; and
   X is Cl, Br, or I.
Aspect 5. The method according to any one of Aspects 1-4, wherein the carbodiimide compound comprises a compound of the formula:

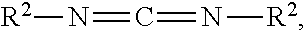

where:
   R² is independently at least one of an alkyl, a cycloalkyl, or any combination thereof.
Aspect 6. The method according to any one of Aspects 1-5,
   wherein the Grignard reagent comprises a compound of the formula:

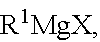

where:
   R¹ is an alkyl; and
   X is Cl, Br, or I,
wherein the carbodiimide compound comprises a compound of the formula:

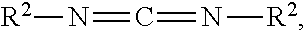

where:
   R² is independently an alkyl.
Aspect 7. The method according to any one of Aspects 1-6,
   wherein the Grignard reagent comprises a compound of the formula:

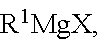

where:
   R¹ is a C₁-C₂ alkyl; and
   X is Cl, Br, or I,
wherein the carbodiimide compound comprises a compound of the formula:

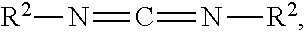

where:
   R² is 1-methylethyl (iso-propyl).
Aspect 8. The method according to any one of Aspects 1-7,
   wherein the Grignard reagent comprises a compound of the formula:

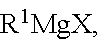

where:
   R¹ is a C₁-C₁₀ alkyl; and
   X is Cl, Br, or I,
wherein the carbodiimide compound comprises a compound of the formula:

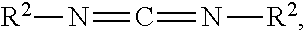

where:
   R² is independently a C₁-C₁₀ alkyl.
Aspect 9. The method according to any one of Aspects 1-8,
   wherein the Grignard reagent comprises a compound of the formula:

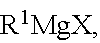

where:
   R¹ is a C₁-C₁₀ alkyl; and
   X is Cl, Br, or I,
wherein the carbodiimide compound comprises a compound of the formula:

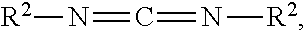

where:
   R² is independently a C₁-C₁₀ cycloalkyl.
Aspect 10. The method according to any one of Aspects 1-9, wherein the vapor deposition precursor comprises a compound of the formula:

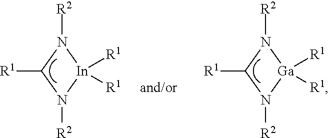

where:
   R¹ is independently at least one of an alkyl, an alkenyl, an alkyne, an aryl, a cycloalkyl, or any combination thereof; and
   R² is independently an alkyl.
Aspect 11. The method according to any one of Aspects 1-10, the vapor deposition precursor comprises a compound of the formula:

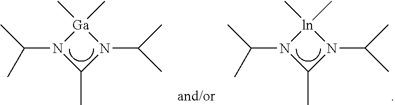

Aspect 12. A composition comprising:
   a vapor deposition precursor comprising a metal amidinate,
      wherein the metal amidinate comprises at least one of a gallium amidinate, an indium amidinate, or any combination thereof;
      wherein the metal amidinate having the characteristics defined by the following process step:
         contacting a metal trihalide, a Grignard reagent, and a carbodiimide compound to form the vapor deposition precursor;
         wherein the metal trihalide comprises at least one of a gallium trihalide, an indium trihalide, or any combination thereof.
Aspect 13. The composition according to Aspect 12, wherein the composition comprises less than 1% by weight of a pyrophoric compound based on a total weight of the composition as assessed by Nuclear Magnetic Resonance.
Aspect 14. The composition according to Aspect 12, wherein the composition comprises less than 0.1% by weight of a pyrophoric compound based on a total weight of the composition as assessed by Nuclear Magnetic Resonance.
Aspect 15. The composition according to any one of Aspects 12-14, wherein the composition does not comprise a pyrophoric compound.
Aspect 16. The composition according to any one of Aspects 12-15, wherein the vapor deposition precursor comprises a compound of the formula:

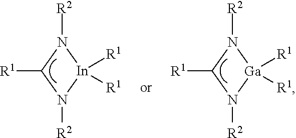

where:
   R¹ is independently at least one of an alkyl, an alkenyl, an alkyne, an aryl, a cycloalkyl, or any combination thereof; and
   R² is independently an alkyl.
Aspect 17. The composition according to Aspect 16, wherein R¹ is an alkyl and wherein R² is an alkyl.
Aspect 18. The composition according to Aspect 16, wherein R¹ is a C₁-C₁₀ alkyl and wherein R² is C₁-C₁₀ alkyl.
Aspect 19. The composition according to Aspect 16, wherein Ri is a C₁-C₁₀ alkyl and wherein R² is C₁-C₁₀ cycloalkyl.
Aspect 20. The composition according to any one of Aspects 12-19, the vapor deposition precursor comprises a compound of the formula:

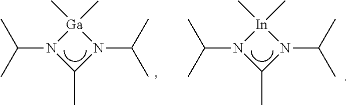

What is claimed is:

1. A method for forming a vapor deposition precursor, the method comprising:
contacting a metal trihalide, a Grignard reagent, and a carbodiimide compound to form the vapor deposition precursor,
wherein the metal trihalide comprises at least one of a gallium trihalide, an indium trihalide, or any combination thereof;
wherein the vapor deposition precursor comprises at least one of a gallium amidinate, an indium amidinate, or any combination thereof.

2. The method of claim 1, wherein the vapor deposition precursor is formed without use of a pyrophoric compound.

3. The method of claim 1, wherein the vapor deposition precursor is formed without use of at least one of trimethyl gallium (Ga(CH₃)₃), dimethyl gallium chloride ((CH₃)₂GaCl), trimethyl indium (In(CH₃)₃), dimethyl indium chloride ((CH₃)₂InCl), methyl lithium, or any combination thereof.

4. The method of claim 1, wherein the Grignard reagent comprises a compound of the formula: 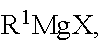
where:
R¹ is at least one of an alkyl, an alkenyl, an alkyne, a cycloalkyl, an aryl, or any combination thereof; and
X is Cl, Br, or I.

5. The method of claim 1, wherein the carbodiimide compound comprises a compound of the formula: 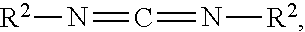
where:
R² is independently at least one of an alkyl, a cycloalkyl, or any combination thereof.

6. The method of claim 1,
wherein the Grignard reagent comprises a compound of the formula: 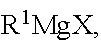
where:
R¹ is an alkyl; and
X is Cl, Br, or I,
wherein the carbodiimide compound comprises a compound of the formula: 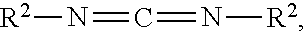
where:
R² is independently an alkyl.

7. The method of claim 1,
wherein the Grignard reagent comprises a compound of the formula: 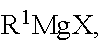
where:
R¹ is a C₁-C₂ alkyl; and
X is Cl, Br, or I,
wherein the carbodiimide compound comprises a compound of the formula: 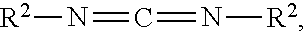
where:
R² is 1-methylethyl (iso-propyl).

8. The method of claim 1,
wherein the Grignard reagent comprises a compound of the formula: 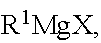
where:
R¹ is a C₁-C₁₀ alkyl; and
X is Cl, Br, or I,
wherein the carbodiimide compound comprises a compound of the formula: 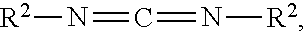
where:
R² is independently a C₁-C₁₀ alkyl.

9. The method of claim 1,
wherein the Grignard reagent comprises a compound of the formula: 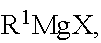
where:
R¹ is a C₁-C₁₀ alkyl; and
X is Cl, Br, or I,
wherein the carbodiimide compound comprises a compound of the formula: 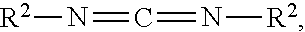
where:
R² is independently a C₁-C₁₀ cycloalkyl.

10. The method of claim 1, wherein the vapor deposition precursor comprises a compound of the formula: 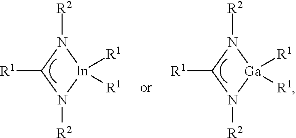
where:
R¹ is independently at least one of an alkyl, an alkenyl, an alkyne, a cycloalkyl, an aryl, or any combination thereof; and
R² is independently an alkyl.

11. The method of claim 1, the vapor deposition precursor comprises a compound of the formula:

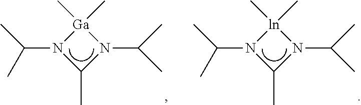

12. A composition comprising:
a vapor deposition precursor comprising a metal amidinate,
wherein the metal amidinate comprises at least one of a gallium amidinate, an indium amidinate, or any combination thereof;
wherein the metal amidinate having the characteristics defined by the following process step:
contacting a metal trihalide, a Grignard reagent, and a carbodiimide compound to form the vapor deposition precursor;
wherein the metal trihalide comprises at least one of a gallium trihalide, an indium trihalide, or any combination thereof.

13. The composition of claim 12, wherein the composition comprises less than 1% by weight of a pyrophoric compound based on a total weight of the composition as assessed by Nuclear Magnetic Resonance.

14. The composition of claim 12, wherein the composition comprises less than 0.1% by weight of a pyrophoric compound based on a total weight of the composition as assessed by Nuclear Magnetic Resonance.

15. The composition of claim 12, wherein the composition does not comprise a pyrophoric compound.

16. The composition of claim 12, wherein the vapor deposition precursor comprises a compound of the formula: 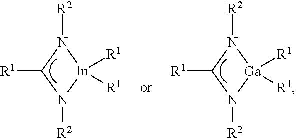
where:
R¹ is independently at least one of an alkyl, an alkenyl, an alkyne, a cycloalkyl, an aryl, or any combination thereof; and
R² is independently an alkyl.

17. The composition of claim 16, wherein R¹ is an alkyl and wherein R² is an alkyl.

18. The composition of claim 16, wherein R¹ is a C₁-C₁₀ alkyl and wherein R² is C₁-C₁₀ alkyl.

19. The composition of claim 16, wherein R¹ is a C₁-C₁₀ alkyl and wherein R² is C₁-C₁₀ cycloalkyl.

20. The composition of claim 12, the vapor deposition precursor comprises a compound of the formula: [chemical structure]
